(19) United States
(12) Patent Application Publication
(10) Pub. No.: US 2024/0164023 A1
(43) Pub. Date: May 16, 2024

(54) METHOD AND SYSTEM FOR PRODUCING CIRCUIT BOARDS WITH PERFORATED SHAPED PARTS

(71) Applicant: JUMATECH GMBH, Eckental (DE)

(72) Inventor: Markus WÖLFEL, Eckental (DE)

(21) Appl. No.: 18/284,397

(22) PCT Filed: Apr. 4, 2022
(86) PCT No.: PCT/EP2022/058858

§ 371 Date: Sep. 27, 2023

(30) Foreign Application Priority Data
Apr. 9, 2021 (DE) 10 2021 108 863.1

(51) Int. Cl. H05K 3/10; H05K 3/00

(52) U.S. Cl. CPC H05K 3/10; H05K 3/0014; H05K 2203/167

(57) ABSTRACT

A method is provided for producing circuit boards with perforated shaped parts. The perforated shaped parts are arranged and fixed relative to one another in a specified configuration in order to form a semi-finished product with a perforated mask, wherein the semi-finished product is then positioned in a press using the perforated mask and is pressed together with at least one other element in order to form a circuit board substrate for producing a circuit board. A system is also provided for producing circuit boards in order to prepare corresponding semi-finished products and processing same in order to form a circuit board substrate for producing a circuit board.

### CROSS REFERENCE TO RELATED APPLICATIONS

This application is a U.S. National Phase application under 35 U.S.C. 371 of International Application No. PCT/EP2022/058858, filed on Apr. 4, 2022, which claims priority to German Patent Application No. 10 2021 108 863.1, filed on Apr. 9, 2021. The entire disclosures of the above applications are expressly incorporated by reference herein.

### TECHNICAL FIELD

The present invention relates to a method and a system for producing circuit boards with perforated shaped parts.

### BACKGROUND

DE 10 2018 203 715 A1 discloses a method for producing circuit boards with at least one conductor extending between connection points. A conductor is arranged in a receptacle of a mold and connected to a metal foil at positions of the intended connection points. The conductor is then embedded in insulating material. Finally, a conductor structure for interconnecting several conductors is worked out of the metal foil, for example, by etching.

In order to achieve reliable interconnection of the embedded conductors by way of the conductor structure, the position of the conductor structure must be precisely matches to the embedded conductors. For this purpose, so-called registration holes, to which the conductor structure is conventionally aligned, are typically inserted into the metal foil. These registration holes are used as reception holes for positioning pins of a press when pressing the elements to be pressed of the circuit board. These holes are then inserted into the inner layers of the circuit board. In this way, all layers of a circuit board to be connected can be aligned in a plane arranged perpendicular to the pressing direction using the positioning pins of the press.

However, there are different shapes of registration holes, such as long holes and round holes, and the positioning accuracy may vary depending on the hole shape.

In addition, the reception holes must always be treated carefully so as not to damage or expand the edges of these reception holes. Otherwise, the positioning accuracy when applying the metal foil to the pins would suffer. In addition, the reception holes are a cost factor—albeit a small one—which, however, is significant with large quantities. Furthermore, the reception holes are almost always disposed in different positions depending on the shape and size of a metal foil. In order to process films of different shapes and sizes, different pressing tools and positioning pins would have to be made available.

### SUMMARY

The present invention is based on the object of providing an improved method and system for the production of circuit boards with which a higher positioning accuracy of the elements to be pressed of a circuit board is made possible during the pressing process.

To satisfy this object, the present invention provides the method according to a first aspect and the system according to a twelfth aspect.

The method according to the invention for producing circuit boards with perforated shaped parts provides that the perforated shaped parts be arranged and affixed with respect to one another in a predetermined configuration in order to form a semi-finished product with a perforated mask, wherein the semi-finished product is thereafter positioned or aligned in a press by means of the perforated mask and is pressed with at least one further element to form a circuit board substrate for producing a circuit board.

The perforated mask is formed by the perforated shaped parts or their reception holes, respectively. In the context of the invention, a two-dimensional or possibly three-dimensional arrangement of at least two openings spaced from one another is referred to as a perforated mask. This perforated mask essentially forms a “lock” into which a “key” fits, namely the arrangement formed by the positioning pins of the press.

In comparison to the conventional method, the main advantage of the invention lies in the fact that the perforated shaped parts are not only—as before—aligned and affixed with respect to one another in the predetermined configuration, but now also serve as reference elements for positioning the semi-finished product formed therewith in the press. Unlike the conventional process, it is no longer necessary to align the shaped parts with respect to holes in the metal foil (electrically conductive surface element). Conversely, the holes in the metal foil (electrically conductive surface element) can be aligned to the shaped parts. As a result, the positioning accuracy can be significantly improved with the method according to the invention because the step of aligning the shaped parts to the registration holes of the metal foil is eliminated.

Advantageous developments of the invention are the objects of other aspects.

In an advantageous further development, the method comprises the steps of:
Step A: Providing a press for pressing elements of the circuit board, where the press comprises positioning pins for positioning the perforated shaped parts during the pressing process.
Step B: Providing perforated shaped parts that have reception holes matched to the outer contours of the positioning pins.
Step C: Providing a mold with which the perforated shaped parts are arrangeable such that they together form a perforated mask into which the positioning pins for positioning the perforated shaped parts can be inserted preferably having a precise fit.
Step D: Arranging the shaped parts using the mold to form the perforated mask.
Step E: Connecting the perforated shaped parts to an electrically conductive surface element and, possibly, an electrically insulating surface element to form a semi-finished product while affixing the perforated mask.
Step F: Positioning the semi-finished product and at least one electrically insulating surface element in the press while introducing the positioning pins into the perforated mask.
Step G: Pressing the semi-finished product with the electrically insulating surface element in the press to embed the perforated shaped parts into the electrically insulating surface element.
Step H: Working out a conductor structure from the electrically conductive surface element to produce the circuit board.

With the mold matched to the press, the semi-finished product can be manufactured with high positioning accuracy and then processed in the press to form a circuit board substrate from which the circuit board is then produced.

It can be advantageous to have the press comprise at least two parts that are movable relative to one another and which are brought together in a pressing direction (e.g. in step G) and pressed against one another with the interposition of the elements to be pressed of the circuit board. The controlled direction of motion of the press parts can further improve the positioning accuracy when pressing the elements of the circuit board since only small transverse forces arise, in particular perpendicular to the pressing direction.

It can be useful to have the semi-finished product be arranged (e.g. in step F) in a plane that is aligned perpendicular to the pressing direction and/or (e.g. in step G) is affixed in a plane that is aligned perpendicular to the pressing direction. In a plane that is aligned perpendicular to the pressing direction, the semi-finished product can be ideally aligned by way of the perforated mask formed by the shaped parts and affixed by the electrically conductive surface element because the smallest transverse forces act there when the elements of the circuit board are pressed.

It can prove useful to have the positioning pins in step F be inserted into the perforated mask in the pressing direction or a direction opposite thereto. This simplifies the positioning of the semifinished product comprising the perforated mask in the press.

It can be practical to have the shaped parts be connected to the electrically conductive surface element in step E by gluing or welding, preferably with the interposition of (electrically conductive) connection sections, in order to preferably penetrate an electrically insulating surface element, which in step E is arranged as a spacer element between the shaped parts and the electrically conductive surface element, and to bridge it mechanically and, possibly, in an electrically conductive manner. In the simplest variant of the method, the shaped parts are connected directly to the electrically conductive surface element. Positive substance-fit adhesive or welded connections between the shaped parts and the electrically conductive surface element are easy to produce and, if necessary, can also be configured to be electrically conductive while creating large contact or transfer surfaces, for example, when using electrically conductive adhesives. In order to embed the shaped parts as completely as possible in insulating material, an electrically insulating surface element can be interposed between the shaped parts and the electrically conductive surface element. For example, a resin-soaked fiber mat (prepreg) can be used as an electrically insulating surface element. In order to obtain a mechanical—possibly also electrically conductive—connection between the shaped parts and the electrically conductive surface element, the electrically insulating surface element must then be bridged, for example, by plate-shaped connection sections which are received in corresponding openings in the electrically insulating surface element. These connection sections can be attached to the shaped parts and fill the respective openings in the electrically insulating surface element in order to terminate flush with the surface of the electrically insulating surface element. The electrically conductive surface element is thereafter positioned on the side of the electrically insulating surface element facing away from the shaped parts and connected, for example, glued or welded to the connection sections. The shaped parts are embedded in insulating material almost entirely and are only indirectly connected to the electrically conductive surface element via the connection sections A contact or transmission surface between the shaped parts and the electrically conductive surface element can be precisely dimensioned by way of these connection sections. This somewhat more complex design entails significant advantages, in particular for high-precision applications.

It can prove useful to have the electrically conductive surface element be perforated, preferably after step E and/or prior to step F, in order to transfer (or expand) the perforated mask onto the electrically conductive surface element. For this purpose, the electrically conductive surface element is perforated, for example, incised, at the locations corresponding to the reception holes of the shaped parts in order to expose the underlying reception holes of the shaped parts. The edges of the reception holes can serve as a guide for a cutting tool (e.g. cutter). The material of the electrically conductive surface element that is cut out is preferably removed or separated from the remainder of the electrically conductive surface element, and possibly also recycled, in particular for producing a new electrically conductive surface element.

It can be helpful to have the semi-finished product be removed from the mold and/or turned over after step E and/or prior to step F so that the electrically conductive surface element points downwards and the perforated shaped parts points upwards. To connect the electrically conductive surface element to the shaped parts, it can be useful to have the electrically conductive surface element be arranged on the surface of the mold in order to cover the shaped parts arranged in the receptacles of the mold. For subsequent processing of the semi-finished product formed from the shaped parts and the electrically conductive surface element in the press, it can be useful to turn the semi-finished product prior to positioning it in the press. Alternatively, it is also possible to use a special mold for arranging the shaped parts in a predetermined configuration, the receptacles of which have contours identical to the shaped parts and which are open towards the top and the bottom. With such a mold, the shaped parts can also be arranged only subsequently on the electrically conductive surface element in the predetermined configuration and finally connected from above to the electrically conductive surface element disposed therebeneath. In this embodiment as well, connection sections and an electrically insulating surface element can be interposed between the shaped parts and the electrically conductive surface element. After connecting the shaped parts to the electrically conductive surface element, the mold, which is open on both sides, can simply be removed upwardly or lifted up, respectively.

It can be useful to have the semi-finished product in step F be positioned in the press with the electrically conductive surface element at the fore, preferably such that the electrically conductive surface element is positioned resting horizontally on a bottom die of the press. The electrically insulating surface element can be placed on the upward-pointing shaped parts and subsequently pressed onto the shaped parts by the upper die of the press in order to embed them in insulating material. For example, a resin-soaked fiber mat (prepreg) can be used as an electrically insulating surface element.

It can prove to be useful in step D to have conductor elements be arranged using the mold and in step E be connected to the electrically conductive surface element and possibly the electrically insulating surface element to form the semi-finished product so that these conductor elements are electrically connected by way of the conductor structure worked out in step H. This allows the elements of the circuit board to be functionally separated. In the context of the present invention, the shaped parts serve primarily as reference elements for positioning the semi-finished product in the press (by way of the perforated mask formed by the reception holes of the shaped parts). In principle, it is possible for the shaped parts to serve not only as reference elements but also to be used as conductor elements and to be formed from electrically conductive material. However, if the shaped parts only serve as reference elements, they do not have to be manufactured from electrically conductive material. In this case, the mechanical strength of the shaped parts is crucial for preventing the reception holes at the positioning pins from tearing out. For this purpose, the shaped parts can be made of plastic material, in particular of fiber-reinforced plastic. Apart from the shaped parts, additional conductor elements can be embedded into insulating material and integrated into the circuit board. Unlike the shaped parts, these conductor elements do not serve as reference elements for positioning in the press and are therefore also not perforated. Even if separate conductor elements are used in addition to the shaped parts, the advantages of the invention are equally achievable because a high level of positioning accuracy of all elements of the circuit board relative to one another can always be achieved using the method according to the invention.

It can be useful to have the perforated shaped parts be in part or entirely made of electrically conductive material and be electrically interconnected by way of the conductor structure worked out in step H. As a result, the shaped parts are not only replaceable as reference or positioning elements but can also be used as conductor elements, in particular for heat dissipation or for connecting electrical components that are mounted on the circuit board.

The object of the invention mentioned at the outset is also satisfied by a system for producing circuit boards, in particular for use in a method according to one of the preceding embodiments, the system comprising:
A press for pressing elements of the circuit board, where the press comprises positioning pins for positioning the perforated shaped parts during the pressing process.
Perforated shaped parts having reception holes matched to the outer contours of the positioning pins.
A mold with which the perforated shaped parts are arrangeable such that they together form a perforated mask into which the positioning pins for positioning the perforated shaped parts can be inserted, preferably having a precise fit.

It can be useful to have the mold comprise for each shaped part at least one dedicated receptacle, the inner contour of which is matched to the outer contour of the shaped part, where the shaped part arranged in the receptacle fills the receptacle preferably entirely and/or a surface of the shaped part extends flush with a surface of the mold. This simplifies the fixation of the perforated mask considerably, for example, by subsequently connecting the shaped parts to an electrically conductive surface element.

It can prove to be useful to have at least one of the shaped parts be arrangeable in different rotational positions in the same receptacle of the mold, preferably such that the reception hole of the shaped part has the same shape and alignment—or different shapes and alignments—in relation to the contour of the mold in these different rotational positions of the shaped part. This reduces the effort for the user when positioning the shaped parts in a respective arrangement and alignment in the receptacles of the mold such that the intended result is achieved. In the simplest case, the shaped parts are formed to be ring-shaped and to have a circular outer circumference and a central reception hole with a circular inner circumference. Such a shaped part can be inserted into a corresponding receptacle of the mold in any rotational position and with the underside as well as the upper side at the fore, where the reception hole always has the same correct alignment relative to the contour of the mold. However, it is also possible to form different perforated masks with shaped parts that produce differently aligned reception holes in different rotational positions with regard to the contour of the mold. For example, positioning tolerances in different directions can be selectively created by using elongate reception holes, where the reception holes of different shaped parts extend in different, in particular mutually perpendicular, directions. Depending on the alignment of the elongate holes relative to the contour of the mold, the directions of the positioning tolerances can be changed. When using two shaped parts with elongate reception holes, the elongate holes can be aligned in two mutually perpendicular directions. Accordingly, one shaped part with its reception hole provides a certain positioning tolerance in a first direction and the other shaped part with its reception hole provides a certain positioning tolerance in a different direction perpendicular thereto. This facilitates aligning the semi-finished product with the perforated mask in a positioning plane. As a result, the positioning tolerances cancel out because the spacing between the two elongate holes corresponds to the spacing between the positioning pins in only one position. The semi-finished product then has a certain movability when aligning with the positioning pins, which makes it easier to attach the semi-finished product to the positioning pins, and the semi-finished product can nevertheless be precisely aligned with the positioning pins.

It can be useful to have each positioning pin comprise an insertion bevel that tapers from a maximum cross section of the positioning pin, which is preferably located at the foot of the positioning pin and preferably fits precisely into the reception hole of a perforated shaped part, to the tip of the positioning pin. This facilitates the insertion of the positioning pin into the perforated mask.

It can be useful to have the shaped parts exhibit at least one of the following properties:
The shaped parts are formed in part or entirely from electrically conductive material.
The shaped parts are produced in part or entirely from metal, preferably copper, or plastic material that is preferably fiber-reinforced, preferably glass fiber-reinforced plastic material.
The shaped parts are formed to be plate-shaped.
The shaped parts have a thickness in the range of 100 and 300 μm, preferably in the range of 150 and 250 μm.
The shaped parts are etched, punched, milled or otherwise formed from a blank.
The shaped parts have a symmetrical, preferably mirror and/or point-symmetrical contour (=outer contour of the shaped part).
The shaped parts have a circular or oval contour.
The shaped parts have a polygonal, in particular rectangular or square contour.

However, it can also be useful to have the reception hole of a shaped part exhibit at least one of the following features:
The reception hole is disposed centrally with respect to the contour of the shaped part.
The reception hole comprises a symmetrical, preferably mirror and/or point-symmetrical contour (=outer contour of the shaped part).
The reception hole has a circular or oval contour.
The reception hole is formed as an elongate hole and preferably has two parallel edges which are preferably connected by semicircular arcs, where the elongate hole particularly preferably in a mold-affixed state of the perforated mask extends in a direction transverse, in particular perpendicular, to another reception hole formed as an elongate hole so that, in connection with positioning pins having a circular cross section, the diameter of which corresponds, for example, to the spacing between the edges of the elongated hole, positioning tolerances arise in two different directions which equalize each other.
The reception hole has a polygonal, in particular rectangular or square contour.
The reception hole is etched, punched, or milled out of the shaped part.

Further advantageous developments of the invention shall arise from combinations of the features disclosed in the description, the claims, and the figures.

### BRIEF DESCRIPTION OF THE DRAWINGS

FIG. 1 shows a schematic top view onto a mold and corresponding shaped parts of the system according to the invention for producing circuit boards according to the method of the invention, where the mold has a rectangular contour and a total of two receptacles with a rectangular contour for receiving perforated shaped parts, each with a rectangular contour, as well as two L-shaped receptacles for corresponding L-shaped conductor elements.

FIG. 2 shows a schematic top view onto the mold according to FIG. 1, where the rectangular shaped parts with an elongate reception hole and the L-shaped conductor elements are received in the corresponding receptacles of the mold in order to fill these receptacles entirely and terminate flush with the surface of the mold, where an electrically conductive surface element is positioned on the surface of this mold and covers the receptacles and the shaped parts as well as conductor elements arranged therein (the contours of these shaped parts and conductor elements are therefore shown in dashed lines), where the electrically conductive surface element is perforated at locations corresponding to the reception holes of the shaped parts so that the perforated mask formed by the reception holes of the shaped parts extends onto the electrically conductive surface element, where a conductor structure to be subsequently worked out of the electrically conductive surface element and consisting of connection points and conductor traces for electrically interconnecting the conductor elements is indicated schematically in a dotted line, where the intended position of the positioning pins of a press in the reception holes of the shaped parts in the intended arrangement of the semi-finished product formed from the shaped parts, conductor elements, and the electrically conductive surface element in the press is also drawn in schematically in dotted lines.

FIG. 3 shows a schematic and lateral exploded view of the arrangement from FIG. 2 before combining the components of the semi-finished product, in particular before arranging the shaped parts and conductor elements in the corresponding receptacles of the mold as well as before positioning the electrically conductive surface element on the surface of the mold to cover the shaped parts and conductor elements arranged in the receptacles.

FIG. 4 shows a schematic lateral view of the arrangement from FIGS. 2 and 3, respectively, after the arrangement of the shaped parts and conductor elements in the corresponding receptacles of the mold and after positioning the electrically conductive surface element on the surface of the mold to cover the shaped parts and conductor elements arranged in the receptacles.

FIG. 5 shows a schematic lateral view of an arrangement, comprising a press and the elements to be pressed therewith of the circuit board, for the explanation of an intermediate step of the method according to the invention, where the semi-finished product and an electrically insulating surface element in the view shown is positioned in the open position of the press between the upper die and the lower die of the press.

FIG. 6 shows a schematic side view of the arrangement according to FIG. 5 in the closed position of the press, where the elements to be pressed of the circuit board are arranged between the upper die and the lower die of the press and are being pressed while the semi-finished product is held in engagement with the positioning pins by way of the perforated mask and positioned in a preferably horizontal plane perpendicular to the (vertical) pressing direction.

FIG. 7 shows a schematic lateral view of a circuit board produced according to the method of the invention, where the perforated shaped parts and conductor elements are embedded in insulating material and, on the surface of the circuit board, a conductor structure for interconnecting the conductor elements is worked out of the electrically conductive surface element, for example, by etching.

### DETAILED DESCRIPTION

The present invention shall be described in detail hereafter with reference to the accompanying figures.

Briefly outlined, the present embodiment relates to a method for producing circuit boards 1 using a mold 6, with which elements to be embedded in circuit board 1, such as shaped parts 2 and possibly conductor elements 12, are positioned relative to one another in a predetermined configuration for connection to an electrically conductive element 8 of surface, such as a copper foil, to form a semi-finished product 9. This semi-finished product 9 produced in this manner is then pressed together with an electrically insulating surface element or an insulating material mat 10 in a press 4 with positioning pins 5. A conductor structure 11 for interconnecting the embedded elements is subsequently worked out of electrically conductive element 8 of surface, for example, by etching.

For the reason that elements 2, 12 to be embedded in circuit board 1 are positioned in mold 6 during the connection to electrically conductive element 8 of surface, they have the intended configuration or alignment to one another as specified by mold 6. In a state connected to electrically conductive element 8 of surface, in which the connected elements form a semi-finished product 9, the configuration or alignment of elements 2, 12 to be embedded, which is predetermined by mold 6, is then affixed relative to one another and can no longer change if semi-finished product 9 is removed thereafter from mold 6.

A similar method is known from DE 10 2018 203 715 A1, the contents of which are incorporated herein by reference.

In deviation from DE 10 2018 203 715 A1, it is not electrically conductive element 8 of surface in the present invention that serves as a reference for positioning elements 2, 12 to be embedded during the pressing process in press 4, but rather perforated shaped parts 2. Electrically conductive element 8 of surface, however, which is used in the context of the present invention, initially has no openings.

Mold 6 is useful for achieving the predetermined configuration of shaped parts 2, but is not absolutely necessary. For example, shaped parts 2 can also be arranged in the predetermined configuration by way of a mask, for example, in the form of markings or projections on electrically conductive element 8 of surface, or by computer-aided positioning.

However, the present embodiment of the method for producing circuit boards 1 with perforated shaped parts 2 uses such a mold 6 and in particular comprises the following steps of:
Step A: Providing a press 4 with positioning pins 5 for positioning perforated shaped parts 2 during the pressing process.

In the present embodiment, press 4 consists of two parts 4a, 4b, namely an upper die 4a and a lower die 4b, which can be moved relative to one another in an e.g. vertical pressing direction P. Lower die 4b comprises a horizontally aligned bearing surface which extends in a horizontal plane E, for example, perpendicular to pressing direction P.

Positioning pins 5 protrude from this plane E in the direction opposite to pressing direction P (e.g. vertically). At the upper end, which faces upper die 4a, positioning pins 5 have insertion bevels. Each insertion bevel tapers, starting from the maximum cross section of positioning pin 5, which has an outer contour matched to a reception hole 3 of a perforated shaped part 2 (see FIG. 2), up to its tip. Upper die 4a has openings corresponding to a perforated mask L into which positioning pins 5 can penetrate when upper die 4a and lower die 4b are pressed together, while penetrating the elements to be pressed of circuit board 1. The number of positioning pins 5 can be freely selected. For example, press 4 has a total of two positioning pins 5, which are disposed, for example, in the diagonally opposite corners of a rectangular bearing surface of lower die 4b. Positioning pins 5 can be configured to be identical or different. Alternatively, it is also possible in principle for positioning pins 5 to be located on upper die 4a, while lower die 4b has corresponding openings for receiving positioning pins 5. In the present example, positioning pins 5 have, for example, a circular cross-sectional shape over their entire length, where the diameter in the region of the insertion bevel reduces towards the tip.
Step B: Providing perforated shaped parts 2 with reception holes 3 matched to the outer contours of positioning pins 5.

Perforated shaped parts 2 preferably have a rectangular, in particular square, oval, or circular contour. As a result, shaped parts 2 can optionally be arranged in several different rotational positions in same receptacle 7 of mold 6, while reception hole 3 respectively has the same shape and alignment to the contour of mold 6. For example, in the case of a circular shaped part 2 with a central round hole, the position and alignment of round hole 3 to the contour of mold 6 is always the same, regardless of which side of this shaped part 2 points upwards or downwards. What is crucial is that reception holes 3 of shaped parts 2 arranged in mold 6 are matched to positioning pins 5 of press 4 with regard to position and alignment. The number of shaped parts 2 corresponds preferably to the number of positioning pins 5 of press 4. However, it is also possible to use shaped parts 2 with several reception holes 3 which are penetrated by several positioning pins 5 so that the number of shaped parts 2 can be fewer than the number of positioning pins 5. In the present case, shaped parts 2 are plate-shaped made of metal, for example, copper, and have a thickness in the range of 100-500 μm, preferably in the range of 200-300 μm. Reception holes 3 are each configured as an elongate hole. The spacing between the two parallel edges of the elongate hole preferably corresponds to the maximum diameter of positioning pins 5. Each positioning pin 5 in the corresponding elongate hole in its direction of extension (see FIG. 2) therefore has a certain positioning tolerance which can be determined by the length of the elongate hole. In one of shaped parts 2, the elongate hole extends parallel to the longer side of the contour of mold 6, in other shaped part 2 parallel to the shorter side of the contour of mold 6. This allows positioning tolerances to be created in two mutually perpendicular directions, which as a result equalize each other.
Step C: Providing mold 6 with which perforated shaped parts 2 are arrangeable such that they together form a perforated mask L into which positioning pins 5 for positioning perforated shaped parts 2 can be inserted preferably having a precise fit.

In the present embodiment, mold 6 has a rectangular contour and two respective rectangular receptacles 7 for rectangular perforated shaped parts 2 and two L-shaped receptacles 13 for L-shaped conductor elements 12. Receptacles 7 for perforated shaped parts 2 are open on one side (e.g. open on the upper side and closed on the underside) and are disposed in diametrically opposite corners of mold 6. However, it is also possible to use a mold 6 that is open on both sides so that the shaped parts can be inserted into receptacles 7 in a state in which mold 6 already rests on electrically conductive element 8 of surface. Receptacles 13 for conductor elements 12 are disposed centrally between receptacles 7 for perforated shaped parts 2. By increasing the spacing between perforated shaped parts 2 from one another, the positioning accuracy of the elements to be embedded in circuit board 2 can be improved. The spacing between corresponding receptacles 7 should therefore be selected to be as large as possible. For example, the most distant receptacles 7 of mold 6 have a spacing of at least 50%, preferably at least 60%, 70% or 80% of the largest dimension of mold 6, which presently corresponds to the diagonal across the rectangular surface of mold 6.
Step D: Arranging shaped parts 2 in a predetermined configuration using mold 6 to form perforated mask L.

The perforated shaped parts are preferably arranged in corresponding receptacles 7 of mold 6 such that each shaped part 2 fills corresponding receptacle 7 entirely and the surface of shaped part 2 terminates flush with the surface of mold 6, possibly also with its underside. In addition to shaped parts 2, conductor elements 12 can optionally also be arranged using mold 6 and aligned precisely with shaped parts 2 in corresponding receptacles 13 for the subsequent connection to electrically conductive element 8 of surface. These conductor elements 12 are particularly advantageous when perforated shaped parts 2 serve only as reference elements for positioning semifinished product 9 in press 4, but do not themselves have an electrically conductive function. These conductor elements 12 can later be electrically connected by way of conductor structure 11 worked out in step H.
Step E: Connecting perforated shaped parts 2 to an electrically conductive element 8 of surface and, possibly, an electrically insulating surface element to form a semi-finished product 8 while affixing perforated mask L.

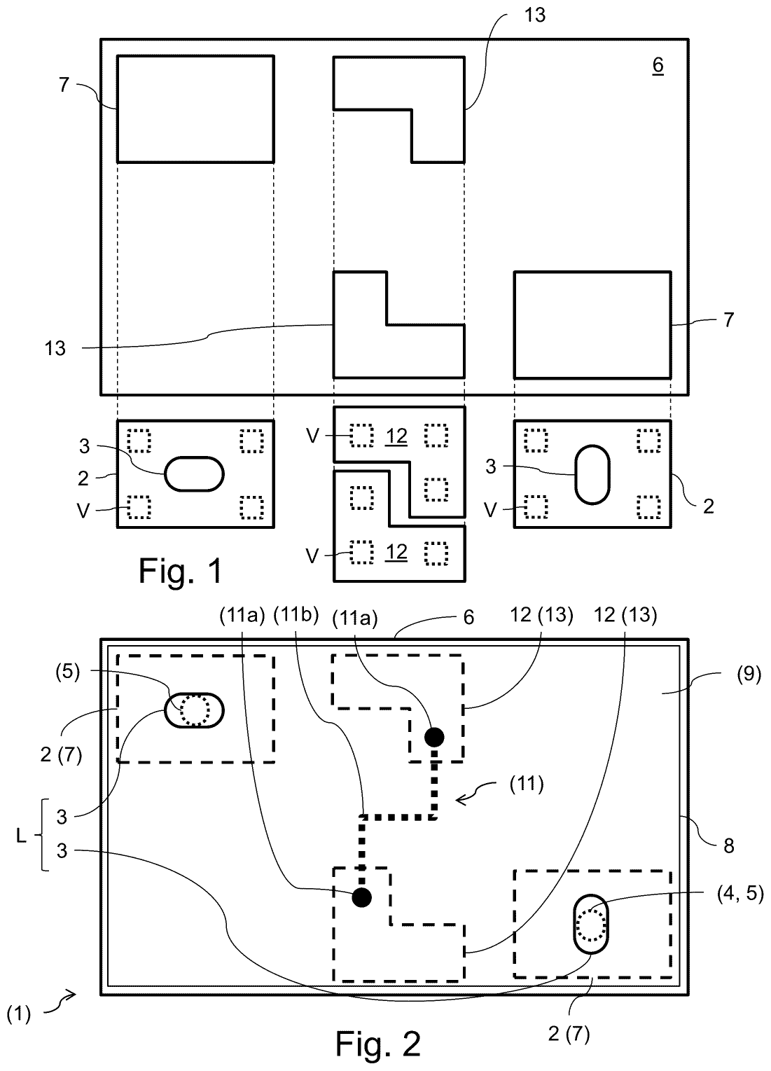

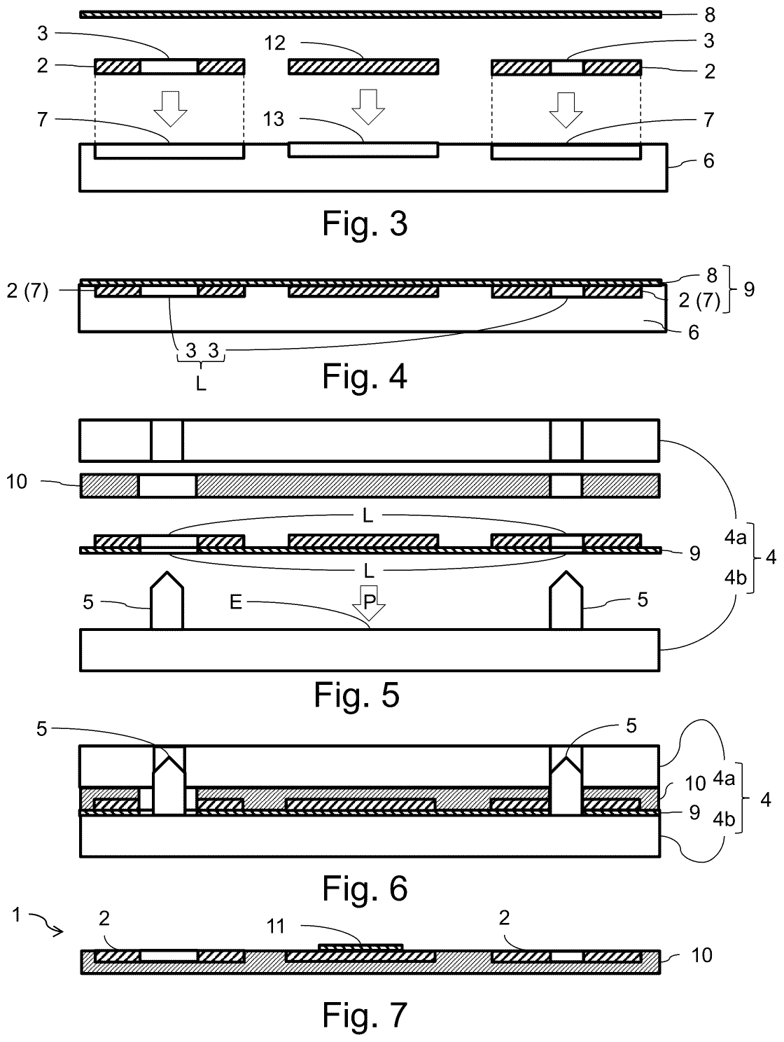

In a simple variant, electrically conductive element 8 of surface is positioned on the upper side of mold 6 and the upper sides being flush therewith of shaped parts 2 arranged in receptacles 7 and connected directly thereto. For example, an unperforated copper foil is used as electrically conductive element 8 of surface. The thickness of this copper foil is preferably in the range of 10-200 μm, preferably in the range of 50-100 μm. Shaped parts 2 are, for example, glued or welded to electrically conductive element 8 of surface. For this purpose, mold 6 can have corresponding die openings, as disclosed in DE 10 2018 203 715 A1. The interposition of electrically conductive connection sections V can be useful for embedding shaped parts 2 entirely in insulating material. Such connection sections V, which are configured, for example, as metal plates, for example, made of silver or copper, are glued or welded, for example, in the corners of shaped parts 2 or conductor elements 12 to the upwardly pointing surface (see FIG. 1). With these connection sections V, an electrically insulating surface element (not shown), which is arranged in step E as a spacer element between shaped parts 2 and electrically conductive element 8 of surface and ideally has exactly the same thickness as connection sections V, can be bridged mechanically and possibly in an electrically conductive manner. Openings with a corresponding contour are inserted in this electrically insulating surface element at the positions matched to connection sections V. When the electrically insulating surface element is arranged on the surface of mold 6, connection sections V fill these openings. The underside of the electrically insulating surface element there rests on the upper side of shaped parts 2 as well as the upper side of mold 6. The upper sides of connection sections V terminate flush with the upper side of the electrically insulating surface element. In this state, electrically conductive element 8 of surface is then glued or welded to connection sections V. The use of connection sections V has the particular advantage that shaped parts 2 and, possibly, conductor elements 12 can be embedded entirely in insulating material and are connected mechanically and optionally in an electrically conductive manner to electrically conductive element 8 of surface only by way of connection sections V. Since the number, shape, and size of connection sections V as well as the contact surfaces to shaped parts 2 or conductor elements 12, on the one hand, and electrically conductive element 8 of surface, on the other hand, can be precisely dimensioned by way of connection sections V, the electrical and thermal resistances therebetween, which are largely determined by connection sections V, can be calculated precisely. However, connection sections V are not absolutely necessary and are therefore only indicated schematically in FIG. 1 by dotted lines. For the sake of simplicity, connection sections V are omitted in the following figures, as is the insulating material mat (electrically insulating surface element) bridged by connection sections V.
Step F: Positioning semi-finished product 9 and at least one electrically insulating element 10 of surface in press 4 while introducing positioning pins 5 into perforated mask L.

For this purpose, semi-finished product 9 previously formed in step E is removed from mold 6 and turned over so that electrically conductive element 8 of surface points downwards and perforated shaped parts 2 point upwards. Semi-finished product 9 is thereafter arranged with electrically conductive element 8 of surface at the fore in press 4 until electrically conductive element 8 of surface is positioned resting horizontally on a lower die 4a of press 4. For this purpose, semi-finished product 9 is “plugged onto” positioning pins 5 from above in pressing direction P so that positioning pins 5 penetrate into perforated mask L and penetrate through semi-finished product 9 in a direction opposite to pressing direction P. Semi-finished product 9 rests on lower die 4b in a plane E that is aligned perpendicular to pressing direction P. By way of perforated mask L, semi-finished product 9 is affixed and aligned by positioning pins 5 in a plane E that is aligned perpendicular to pressing direction P. Ideally, electrically conductive element 8 of surface is perforated after step E and prior to step F in order to transfer perforated mask L onto electrically conductive element 8 of surface. For this purpose, the parts of electrically conductive element 8 of surface are perforated within the edges of reception holes 3 of shaped parts 2, for example, cut out, so that semi-finished product 9 fits exactly onto positioning pins 5 of press 4. Alternatively, it is also possible to perforate electrically conductive element 8 of surface only when semi-finished product 9 is plugged onto positioning pins 5 of press 4 and to pierce it with them. However, there is then the risk that parts of electrically conductive element 8 of surface remain connected to the remainder of electrically conductive element 8 of surface within the edges of reception holes 3 of shaped parts 2 and create unwanted electrical connections.
Step G: Pressing semi-finished product 9 with electrically insulating element 10 of surface in press 4 to embed perforated shaped parts 2 into electrically insulating element 10 of surface.

For this purpose, upper die 4a and lower die 4b are brought together in pressing direction P and pressed against each other with the interconnection of the elements to be pressed of circuit board 1. Electrically insulating element 10 of surface is there deformed and hugs the contour of shaped parts 2 and possibly conductor elements 12. The upper side of electrically insulating element 10 of surface, which points away from lower die 4b, is there flattened by upper die 4a and aligned parallel to the downward-pointing side of electrically conductive element 8 of surface. When using a resin-soaked fiber mat (prepreg) as electrically insulating element 10 of surface, the latter is pressed in a state in which the resin is still flowable and adapts ideally to the contour formed by shaped parts 2 and possibly conductor elements 12 on the upward-pointing side of semi-finished product 9. After semi-finished product 9 has been pressed with electrically insulating element 10 of surface, the resin is cured to affix the shape of the circuit board substrate.
Step H: Working out a conductor structure 11 from electrically conductive element 8 of surface to produce circuit board 1.

This step is accomplished, for example, by etching electrically conductive element 8 of surface according to a predetermined mask. For this purpose, the circuit board substrate produced by pressing semi-finished product 9 with electrically insulating element 10 of surface is first removed from the press and ideally turned over so that electrically conductive element 8 of surface points upwards again. A mask corresponding to conductor structure 11 is then applied to electrically conductive element 8 of surface in order to cover the areas of electrically conductive element 8 of surface that correspond to conductor structure 11. The remaining areas of electrically conductive element 8 of surface are removed thereafter, for example, by etching. In the present example, conductor structure 11 comprises connection points 11a and conductor traces 11b. Connection points 11a are used for the electrical connection of electronic elements to underlying embedded shaped parts 2 or conductor elements 12. A conductive connection between connection points 11a can be established by way of conductor traces 11b, but also by way of shaped parts 2 or conductor elements 12. Shaped parts 2 or conductor elements 12 are preferably electrically connected by way of conductor structure 11 worked out in step H.

The system according to the invention for producing circuit boards 1, in particular for use in the method described above, comprises the following elements:
A press 3 for pressing elements of circuit board 1, where press 4 comprises positioning pins 5 for positioning perforated shaped parts 2 during the pressing process.
Perforated shaped parts 2 with reception holes 3 matched to the outer contours of positioning pins 5.
A mold 6 with which perforated shaped parts 2 are arrangeable such that they together form a perforated mask L into which positioning pins 5 for positioning perforated shaped parts 2 can be inserted, preferably having a precise fit.

With these three matched components, the alignment of elements 2, 12 to be embedded with respect to conductor structure 11 of circuit board 1 can be improved.

Mold 5 preferably comprises for each shaped part 2 a dedicated receptacle 7, the inner contour of which is matched to the outer contour of shaped part 2, so that shaped part 2 arranged in receptacle 7 fills receptacle 7 preferably entirely and a surface of shaped part 2 extends flush with a surface or possibly an underside of mold 6. These variants facilitate connecting perforated shaped parts 2 to an electrically conductive element 8 of surface to form a semi-finished product 9.

Preferably, shaped parts 2 are arrangeable in different rotational positions in same receptacle 7 of mold 6, while reception hole 3 of shaped part 2 has the same shape and alignment—or different shapes and alignments—in relation to the contour of mold 2 in these different rotational positions of shaped part 2. This reduces the effort for a user of this system to position shaped parts 2 in the correct position and alignment in mold 6.

Each positioning pin 5 preferably has an insertion bevel which tapers from a maximum cross section of positioning pin 5, which is preferably located at the foot of positioning pin 5 and preferably fits precisely into reception hole 3 of a perforated shaped part 2, to the tip of positioning pin 5. This facilitates positioning a semi-finished product 9 formed with shaped parts 2 and electrically conductive element 8 of surface in press 4.

The present embodiment is chosen for illustrative purposes only and is not based on real circumstances, in particular not on realistic dimensions. The shape and size of mold 6, as well as the shape, size, as well as the position and alignment of receptacles 7 can be freely selected within the scope of the teaching according to the invention and are not restricted to the present embodiment.

As a result, the method according to the invention enables precise positioning of the elements to be pressed of circuit board 1 without effort and without restrictions with regard to the size, shape, and position of reception holes 3.

1-15. (canceled)

16. A method for producing circuit boards having perforated shaped parts, wherein said perforated shaped parts are arranged and affixed with respect to one another in a predetermined configuration in order to form a semi-finished product with a perforated mask, wherein said semi-finished product is thereafter positioned or aligned in a press by said perforated mask and is pressed with at least one further element to form a circuit board substrate for producing a circuit board.

17. The method according to claim 16, comprising the steps of:
a. Step A: Providing a press for pressing elements of said circuit board, wherein said press comprises positioning pins for positioning said perforated shaped parts during the pressing process;
b. Step B: Providing perforated shaped parts that have reception holes matched to the outer contours of said positioning pins;
c. Step C: Providing a mold with which said perforated shaped parts can be arranged such that they together form a perforated mask into which said positioning pins for positioning said perforated shaped parts can be inserted;
d. Step D: Arranging said shaped parts using said mold to form said perforated mask;
e. Step E: Connecting said perforated shaped parts to an electrically conductive surface element and selectively an electrically insulating surface element to form a semi-finished product while affixing said perforated mask;
f. Step F: Positioning said semi-finished product and at least one electrically insulating surface element in said press while introducing said positioning pins into said perforated mask;
g. Step G: Pressing said semi-finished product with said electrically insulating surface element in said press to embed said perforated shaped parts into said electrically insulating surface element; and
h. Step H: Working out a conductor structure from said electrically conductive surface element to produce said circuit board.

18. The method according to claim 16, wherein said press comprises at least two parts that are movable relative to one another and which are brought together in a pressing direction and pressed against one another with the interposition of said elements to be pressed of said circuit board.

19. The method according to claim 16, wherein said semi-finished product is arranged in a plane that is aligned perpendicular to a pressing direction and/or is affixed in a plane that is aligned perpendicular to said pressing direction.

20. The method according to claim 16, wherein positioning pins of said press are inserted into said perforated mask in said pressing direction or a direction opposite thereto.

21. The method according to claim 16, wherein said shaped parts are connected to said electrically conductive surface element in step E by gluing or welding, with the interposition of connection sections, to penetrate an electrically insulating surface element, which in step E is arranged as a spacer element between said shaped parts and said electrically conductive surface element, and to bridge it mechanically.

22. The method according to claim 21, wherein said spacer element between said shaped parts and said electrically conductive surface element further bridges it electrically conductively.

23. The method according to claim 16, wherein said electrically conductive surface element is perforated, after step E and/or prior to step F, in order to transfer said perforated mask to said electrically conductive surface element.

24. The method according to claim 16, wherein said semi-finished product is removed from said mold and/or turned over after step E and/or prior to step F so that said electrically conductive surface element points downwards and said perforated shaped parts point upwards.

25. The method according to claim 16, wherein said semi-finished product in step F is positioned in said press with said electrically conductive surface element at the fore, such that said electrically conductive surface element is positioned resting horizontally on a bottom die of said press.

26. The method according to claim 16, wherein conductor elements are arranged in step D using said mold and connected in step E to said electrically conductive surface element, and selectively to said electrically insulating surface element, to form said semi-finished product so that these conductor elements are electrically interconnected by way of said conductor structure worked out in step H.

27. The method according to claim 16, wherein said perforated shaped parts are in part or entirely formed from electrically conductive material and are electrically interconnected by way of said conductor structure worked out in step H.

28. A system for producing circuit boards for use in the method according to claim 16, said system comprising:
a. A press for pressing elements of said circuit board, wherein said press comprises positioning pins for positioning said perforated shaped parts during the pressing process;
b. Perforated shaped parts with reception holes matched to the outer contours of said positioning pins; and
c. A mold with which said perforated shaped parts are arrangeable such that they together form a perforated mask into which said positioning pins for positioning said perforated shaped parts can be inserted.

29. The system according to claim 28, wherein said mold comprises for each shaped part at least one dedicated receptacle, the inner contour of which is matched to the outer contour of said shaped part, wherein said shaped part arranged in said receptacle fills said receptacle entirely and/or a surface of said shaped part extends flush with a surface of said mold.

30. The system according to claim 28, wherein at least one of said shaped parts is arrangeable in the same receptacle of said mold in different rotational positions, such that said reception hole of said shaped part has the same contour and shape, or different contours and shapes, in relation to the contour of said mold in these different rotational positions of said shaped part.

31. The system according to claim 28, wherein each positioning pin comprises an insertion bevel that tapers from a maximum cross section of said positioning pin, which is located at a foot of said positioning pin and fits precisely into said reception hole of a perforated shaped part, to a tip of said positioning pin.
